(19) United States
(12) Patent Application Publication
(10) Pub. No.: US 2024/0086602 A1
(43) Pub. Date: Mar. 14, 2024

(54) CLOCK RELATIONSHIP BASED RE-CONVERGENCE ANALYSIS

(71) Applicant: Synopsys, Inc., Mountain View, CA (US)

(72) Inventors: Anchit JAIN, Uttar Pradesh (IN); Deepak AHUJA, New Delhi (IN); Paras Mal JAIN, Cupertino, CA (US)

(21) Appl. No.: 18/235,308

(22) Filed: Aug. 17, 2023

(30) Foreign Application Priority Data
Sep. 14, 2022 (IN) 202241052561

(51) Int. Cl. G06F 30/33

(52) U.S. Cl. CPC G06F 30/33

(57) ABSTRACT

A clock relationship based re-convergence analysis method includes receiving, by a processing device, a register-transfer level (RTL) description of a design relating to an integrated circuit (IC). The method further includes identifying one or more clock domain crossing (CDC) synchronizers in the RTL description of the design, and generating a levelized topological abstract graph (LTAG) including a network of nodes. Each node includes a CDC synchronizer. The method further includes traversing the LTAG starting from a first output of the one or more CDC synchronizers, and responsive to determining that a first CDC synchronizer of the one or more CDC synchronizers is converging with a second CDC synchronizer, identifying a first potential convergence violation associated with the first CDC synchronizer and the second CDC synchronizer.

### CROSS REFERENCE TO RELATED APPLICATIONS

This application claims priority of Indian Provisional Patent Application No. 202241052561 filed on Sep. 14, 2022, titled “Clock Relationship Based Re-Convergence Analysis,” the entire contents of which is incorporated herein by reference.

### TECHNICAL FIELD

The present disclosure relates to electronic design automation. More specifically, one or more embodiments disclosed herein relate to verification of integrated circuit design using clock domain cross verification.

### BACKGROUND

As design size and complexity of electronic circuits increase, design verification becomes more and more difficult. A typical system-on-chip (SoC) contains multiple blocks assigned to multiple teams of engineers. This can present challenges in verifying the SoC, especially relating to capacity and debug, because a block owner (e.g., an engineer or team of engineers) may not be able to analyze violations relating to blocks that are assigned to another owner.

### SUMMARY

In one embodiment, a method includes receiving, by a processing device, a register-transfer level (RTL) description of a design relating to an integrated circuit (IC). The method further includes identifying one or more clock domain crossing (CDC) synchronizers in the RTL description of the design, and generating a levelized topological abstract graph (LTAG) including a network of nodes. Each node includes a CDC synchronizer or a circuit element. The method further includes traversing the LTAG starting from a first output of the one or more CDC synchronizers, and responsive to determining that a first CDC synchronizer of the one or more CDC synchronizers is converging with a second CDC synchronizer, identifying a first potential convergence violation associated with the first CDC synchronizer and the second CDC synchronizer.

The method further includes identifying a plurality of converging CDC synchronizers, and creating one or more subsets including one or more of the plurality of converging CDC synchronizers based on a clock-relationship between the plurality of converging CDC synchronizers. The method further includes traversing the LTAG starting from a second output of the one or more CDC synchronizers, comparing a first subset at a gate in the IC to a second subset on a fan-in node in the network of nodes, and responsive to determining that the first subset matches with the second subset, identifying the first subset as suppressed. The method further includes propagating each unsuppressed convergence over the LTAG to one or more end points, and responsive to determining that a first end point has a synchronous clock relationship with the first CDC synchronizer, identifying the first end point as a second potential convergence violation. The method further includes suppressing one or more converging CDC synchronizers with no end points, and generating a report including one or more unsuppressed converging CDC synchronizers.

Another embodiment is a non-transitory computer readable medium including stored instructions, which when executed by a processor, cause the processor to receive a register-transfer level (RTL) description of a design relating to an integrated circuit (IC). The instructions further cause the process to identify one or more clock domain crossing (CDC) synchronizers in the RTL description of the design, and generate a levelized topological abstract graph (LTAG) including a network of nodes. Each node includes a CDC synchronizer or a circuit element. The instructions further cause the process to traverse the LTAG starting from a first output of the one or more CDC synchronizers, and responsive to determining that a first CDC synchronizer of the one or more CDC synchronizers is converging with a second CDC synchronizer, identify a first potential convergence violation associated with the first CDC synchronizer and the second CDC synchronizer.

Another embodiment is a system including a processor and a memory storing instructions, which when executed by the processor, cause the processor to perform operations including receiving a register-transfer level (RTL) description of a design relating to an integrated circuit (IC). The operations further include identifying one or more clock domain crossing (CDC) synchronizers in the RTL description of the design, and generating a levelized topological abstract graph (LTAG) including a network of nodes. Each node includes a CDC synchronizer or a circuit element. The operations further include traversing the LTAG starting from a first output of the one or more CDC synchronizers, and responsive to determining that a first CDC synchronizer of the one or more CDC synchronizers is converging with a second CDC synchronizer, identifying a first potential convergence violation associated with the first CDC synchronizer and the second CDC synchronizer.

### BRIEF DESCRIPTION OF THE DRAWINGS

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale.

FIG. 1 illustrates a block diagram of an integrated circuit (IC) with a convergence issue.

FIG. 2 illustrates a clock diagram of the IC with the convergence issue shown in FIG. 1.

FIG. 3 illustrates a block diagram of another integrated circuit (IC) with another convergence issue.

FIGS. 4A and 4B illustrate example operations in a method for performing a clock relationship based re-convergence analysis, in accordance with an embodiment of the present disclosure.

FIG. 5A illustrates a block diagram of an integrated circuit (IC) for performing a clock relationship based re-convergence analysis, in accordance with an embodiment of the present disclosure.

FIG. 5B illustrates a levelized topological abstract graph (LTAG) including a network of nodes, in accordance with an embodiment of the present disclosure.

FIG. 6 depicts a flowchart of various processes used during the design and manufacture of an integrated circuit in accordance with some embodiments of the present disclosure.

FIG. 7 depicts a diagram of an example computer system in which embodiments of the present disclosure may operate.

### DETAILED DESCRIPTION

Re-convergence issues can arise in an IC when multiple signals cross from one domain to another but are separately synchronized. Some clock domain cross verification tools may be able to perform re-convergence checks and enable the user to ensure that there is reliable transfer of signals between two parts of circuits driven by two different clocks which are asynchronous to each other. It may be unreliable, however, to sample a signal at a destination data register (e.g., a flip-flop or a latch element) on the destination data register's clock edge when the signal is changing at the source data register (e.g., a flip-flop or a latch element) at the source data register's clock edge. The signal sampled at such a point in time does not assume a stable ‘0’ or ‘1’ value, and is therefore metastable. The effect of a metastable signal can be neutralized by introducing synchronizers, which may be a chain of flip-flops that are driven by a destination clock after the crossing. However, even if each crossing has the necessary synchronizer to transfer a signal reliably to the destination side, there can still be functional failure if two or more source signals (either originating from the same signal, or from two or more related signals) are synchronized at different cycles at the destination side, and then converge at a downstream location. Such a functional issue is termed as a “coherency” issue. Some low noise clock domain cross verification tools support a check which flags such kinds of violations. However, in these re-convergence checks, there are two problems.

First, the re-convergence issue is flagged only when the sources are synchronized in the same destination clock domain (e.g., synchronizers are driven by same clock-net). However, if multiple clocks are driving the synchronizer registers, then clock-relationships among different registers are not considered, which can lead to a miss of a potential re-convergence issue in the system-on-chip (SOC) and cause a functional failure in the design. Second, a violation is flagged by the re-convergence checks, even if the converging synchronizers are driving a register which is driven by a clock having an asynchronous relationship with the clocks driving the synchronizers. Such a violation can be considered noise to the synchronizer clocks, as it is a metastability issue and not a coherency issue.

Aspects of the present disclosure relate to methods for identifying coherency issues in register-transfer level (RTL) designs, which can occur due to divergence and re-convergence of synchronizer objects having a synchronous clock-relationship. In one embodiment, the method identifies the clock domain crossing (CDC) synchronizers in the RTL description of the design, and generates a levelized topological abstract graph (LTAG) including a network of nodes. Each node includes a CDC synchronizer or a circuit element. The method further includes traversing the LTAG, starting from a first output of a CDC synchronizer in a node, and identifying one or more converging points where a first CDC synchronizer is converging with a second CDC synchronizer. The method further includes identifying a first potential convergence violation associated with the first CDC synchronizer and the second CDC synchronizer, and generating a report including information identifying the converging CDC synchronizers.

Advantages of the present disclosure include, but are not limited to, ease of integration of the disclosed methodologies into any simulation tool. Such a simulation tool may be able to identify potential chip killer issues early at the RTL implementation stage. Additionally, end-point analysis provided in the disclosed systems and methods result in reduction of noisy violations thus reducing bandwidth requirement. Additionally, the methods and systems disclosed are highly performance optimized with better turnaround time for solving complex problems, resulting in less processor utilization and less memory requirement.

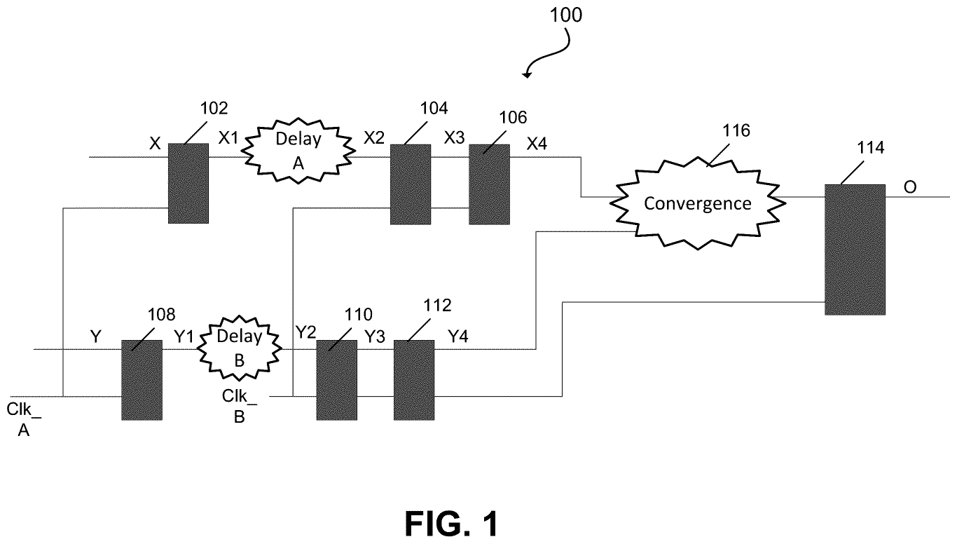

FIG. 1 illustrates a block diagram of an integrated circuit (IC) 100 with a convergence issue. IC 100 includes flip-flops 102, 104, 106, driven by Clk_A, flip-flops 108, 110, 112, driven by Clk_B, and a seventh flip-flop 114 with output port O. In this example, the source signals X1 and Y1 (driven by Clk_A) are synchronized at the destination side by respective synchronizer flip-flops (driven by Clk_B, which is asynchronous to Clk_A). However, here the re-convergence issue at location 116 is flagged only when the sources are synchronized in the same destination clock domain (e.g., synchronizers are driven by same clock-net).

Static convergence violations can be reported when two or more synchronizers merge at a point. The merging point is called the convergence point. The decision whether to report convergence of any two qualifiers (e.g., synchronizers or flip-flops) depends on multiple factors such as the relationship between the clocks driving the destination of the qualifiers, the relationship between the clocks driving the source of the qualifiers, and the relationship between the clocks driving the destination of the qualifiers and the relationship of clocks of the end-points (register/port/black-box) driven by the convergence point. In some implementations, the analysis is based on a composite-clock analysis. The two factors taken into consideration are that the destination-clocks of the qualifiers should be in the same domain, and that the source-clocks of the qualifiers can either be in the same domain or in a different domain. However, there are several limitations with this approach which can lead to missing real violations in the design which can cause a chip-failure.

Convergence of two qualifiers that share at least one synchronous clock-pair and whose destinations are driven by different clocks is possible. Having one synchronous clock-pair implies the possibility of a mode where both the qualifiers may be active at the same time and can introduce coherency. Similar criteria for source-clocks of qualifier should be considered when the destination clock criteria match, i.e. if at least one synchronous clock-pair on among source-clocks exist, then only the convergence violation should be reported. If the criteria does not match, then the violation severity is different.

An end-point can defined as a register/port/black-box, such that there exists at least one synchronous clock-pair between the destination-clocks of the qualifier and the clocks driving the end-point. For a convergence-violation to be considered valid, it must drive at least one valid end-point.

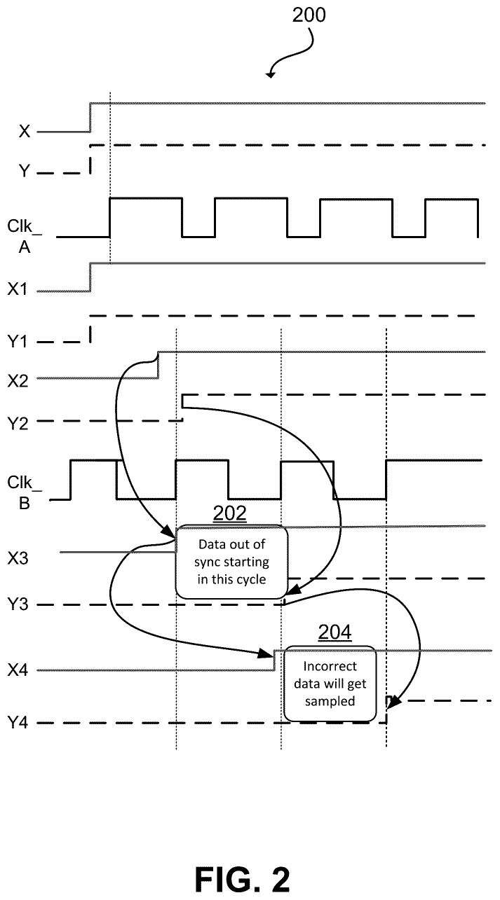

FIG. 2 illustrates a clock diagram 200 of the IC with the convergence issue shown in FIG. 1. As seen in this figure, data starts to go out of sync in the second cycle 202 of Clk_B, becomes more pronounced in the third cycle, and by the time for the fourth cycle 204 of Clk_B, incorrect data may get sampled because of the convergence issue shown in FIG. 1.

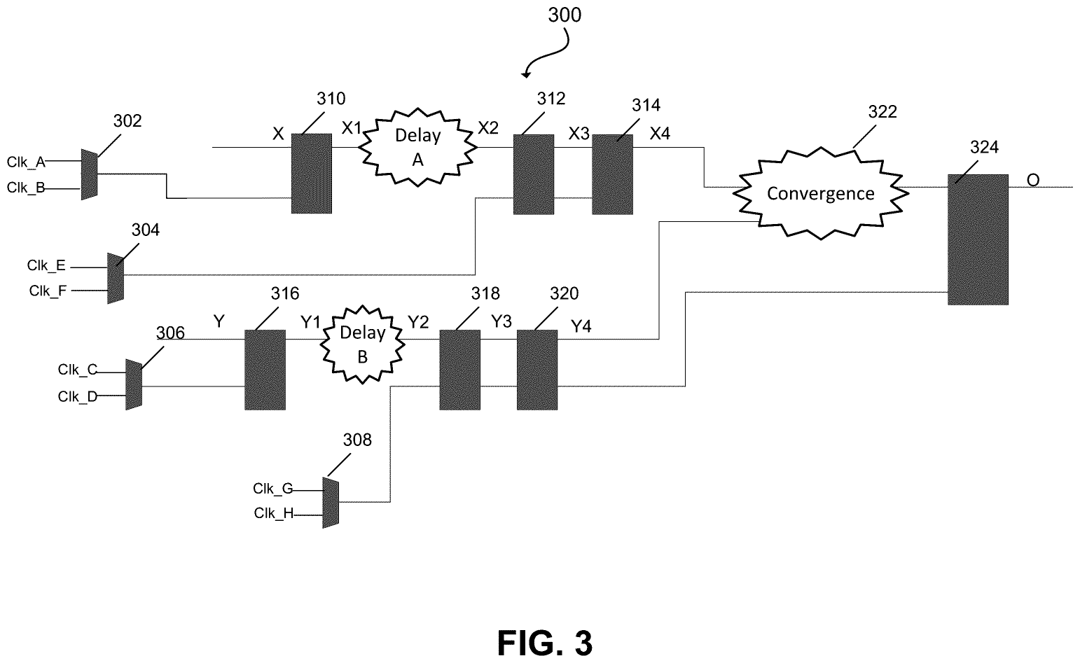

FIG. 3 illustrates a block diagram of another integrated circuit (IC) 300 with a convergence issue 322. IC 300 includes multiplexer 302 coupled to flip-flop 310, and additional flip-flops 312, 314. IC 300 also includes multiplexer 304 coupled to flip-flop 312, and additional flip-flops 314. IC 300 also includes multiplexer 306 coupled to flip-flop 316, and additional flip-flops 318, 320. IC 300 also includes multiplexer 308 coupled to flip-flop 318, and additional flip-flop 320, and a flip-flop 324 with output O. In this example, the source X1 (driven by Clk_A and Clk_B) and Y1 (Clk_C and Clk_D) are synchronized at the destination side by respective synchronizer flip-flops X4 (driven by Clk_E and Clk F) and Y4 (drive by Clk_G and Clk H). The clock relationship among the various clocks can be described as follows: the relationship between CLK_A and CLK_C is synchronous, the relationship between CLK_E and CLK_G is synchronous, and the relationship between all the other clock-pairs is asynchronous. In such a structure, a coherency can happen in one mode when the source registers X and Y are active with respect to clocks Clk_A and Clk_C respectively, and the destination side is synchronized with respect to clock Clk_E and Clk_G respectively. Such a re-convergence/coherency issue is not flagged by certain re-convergence checks. This can lead to a miss in potential re-convergence issue in the SoC and cause a functional failure in the RTL design.

A violation can be flagged by the certain re-convergence checks, even if the converging synchronizers are driving a register which is driven by a clock having an asynchronous relationship with the clocks driving the synchronizers. Such a violation can be considered noise to the synchronizer clocks as it is a metastability issue and not a coherency issue. The systems and methods disclosed herein identify and flag the missing violations and suppress the noisy violations, as described below. This type of convergence checks whether there exists a relation between two qualifier objects based on the clocks that are driving the destination and source of the qualifier.

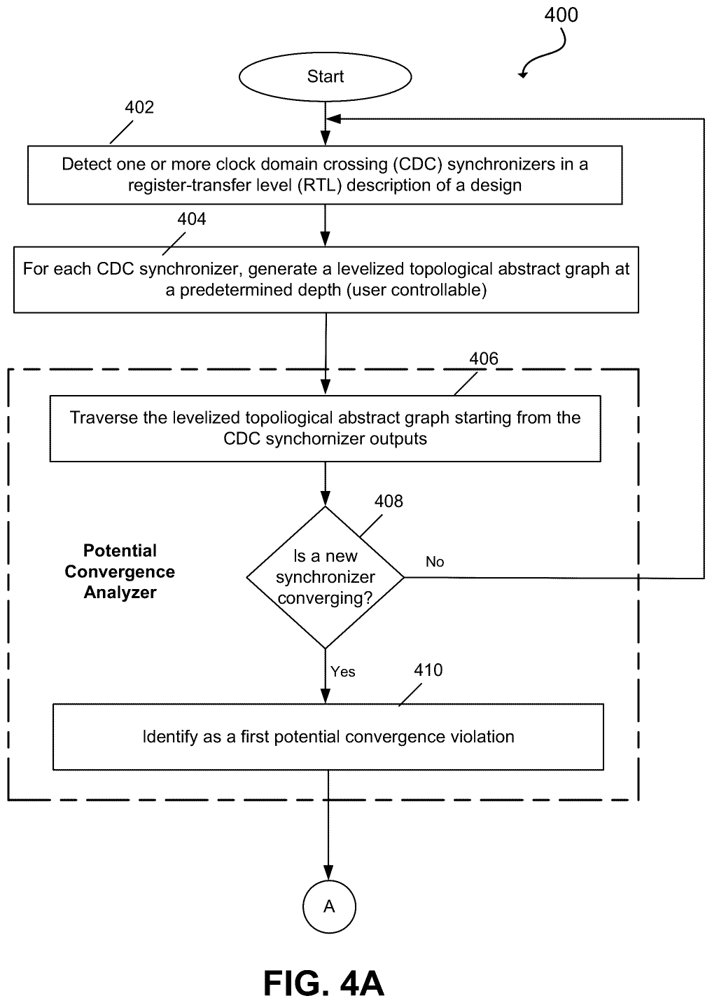

FIGS. 4A and 4B illustrate example operations in a method 400 for performing a clock relationship based re-convergence analysis, in accordance with an embodiment of the present disclosure. The method 400 includes receiving, by a processing device, a register-transfer level (RTL) description of a design relating to an integrated circuit (IC). At operation 402, the processing device identifies one or more clock domain crossing (CDC) synchronizers in the RTL description of the design, and generates a levelized topological abstract graph (LTAG) including a network of nodes, at operation 404. The graph may be levelized in such a manner that each level may have a set of nodes which may not have value dependencies, and each node may include a CDC synchronizer or a circuit element. At operation 406, the processing device traverses the LTAG (e.g., checks each point in the IC for any potential convergence violations by conducting a breadth-first search (BFS)) starting from an output of a CDC synchronizer in one of the nodes. Graph traversal is a process of visiting all the nodes from a source node only once in some defined order. The order of traversal of nodes of a graph is very important while solving some graph problems. Also, one must track the nodes that are already visited because, in traversal, there is a need to traverse a node only once. So, a proper list of the traversed nodes of the graph must be maintained. Breadth-first search (BFS) is an algorithm for traversing or searching tree or graph data structures. It starts at the tree root and explores the neighbor nodes first, before moving to the next level neighbors.

Based on the source node, the whole graph can be divided into various levels, e.g., the nodes that are at distance 1 from the source node are said to be at level 1. Similarly, the nodes that are at distance 2 from the source node are said to be at level 2 and so on. Based on the layers of the graph, the BFS can be performed by starting with the starting or source node, traversing all the nodes present in level 1 of the graph, and moving to the next level and traverse all the nodes present in level 2 and so on.

At operation 408, the processing device determines whether a first CDC synchronizer of the one or more CDC synchronizers is converging, and in response to determining that the first CDC synchronizer is converging, identifies a first potential convergence violation associated with the first CDC synchronizer, at operation 410. If it is determined that the first CDC synchronizer is not converging, then the process goes back to operation 402.

Violations can be categorized based on two criteria: sequential depth and relationship among source-clocks of the qualifiers (e.g., synchronizers or flip-flops). Under sequential depth, tf all the qualifiers at a point of convergence are propagated with 0 sequential depth, then it is determined to be a combinational convergence. If at least one qualifier at a point of convergence is propagated with a sequential depth of greater than zero, then it is determined to be a sequential convergence. Under relationship among source-clocks of the qualifiers, if source-clocks of all the qualifiers in a violation are synchronous (for each configuration), then it is determined to be a sync-source convergence. If at least one qualifier in a violation does not have a synchronous clock-relationship, then it is determined to be an asynchronous convergence. In asynchronous convergence violation, if there exists at least two qualifiers with a sync source clock relationship (based on value of clock_relation_criteria), then the corresponding sync-source convergence can be generated.

Turning now to FIG. 4B, the method 400 further includes identifying multiple converging CDC synchronizers, and at operation 414, creating one or more subsets including one or more of the plurality of converging CDC synchronizers based on a clock-relationship between the plurality of converging CDC synchronizers. At operation 416, the processing device is further configured to traverse the LTAG (e.g., checks each point in the IC for any potential convergence violations by conducting a breadth-first search (BFS)) starting from a second output of the one or more CDC synchronizers. At operation 418, the processing device is further configured to compare a first subset at a gate in the IC to a second subset on a fan-in node in the network of nodes, and responsive to determining that the first subset matches with the second subset, identify the first subset as suppressed (marked as false) at operation 420.

The method 400 further includes, at operation 422, propagating each unsuppressed convergence over the LTAG to one or more end points. Each end-point may include a sequential register, black-box, or a primary port. At operation 424, responsive to determining that a first end point has a synchronous clock relationship with the first CDC synchronizer, the processing device identifies the first end point as a second potential convergence violation, at operation 426. At operation 428, the processing device is further configured to suppress one or more converging CDC synchronizers with no end points, and generate a report including one or more unsuppressed converging CDC synchronizers, at operation 430.

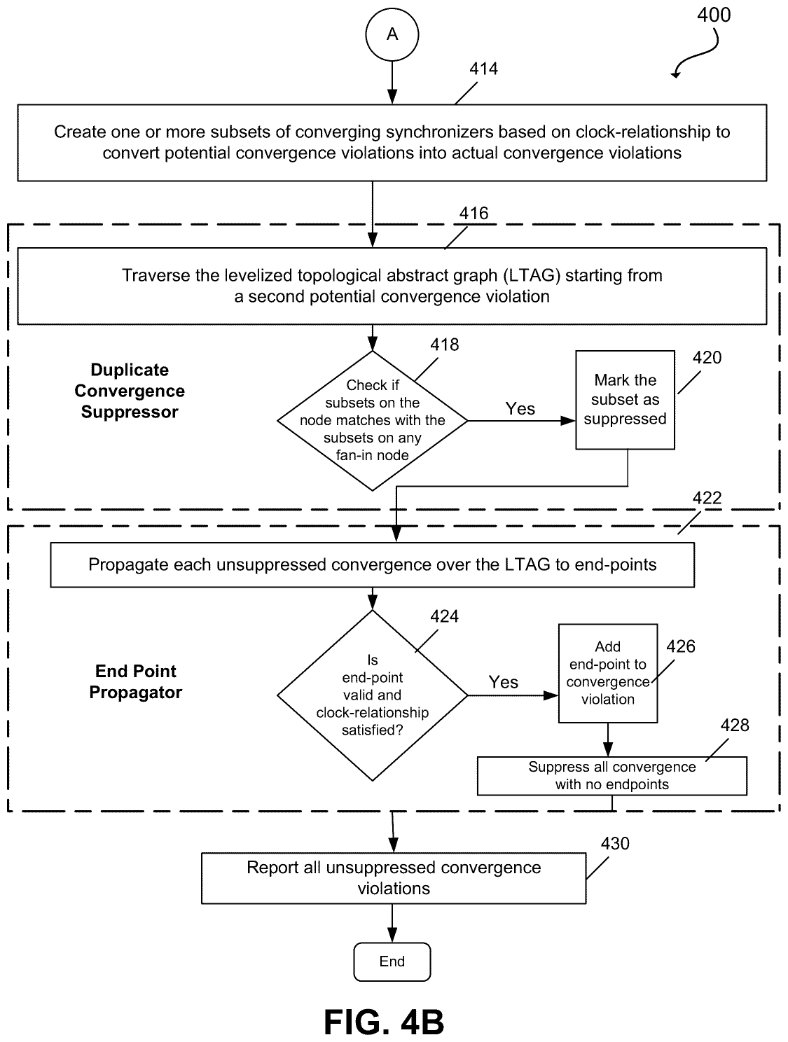

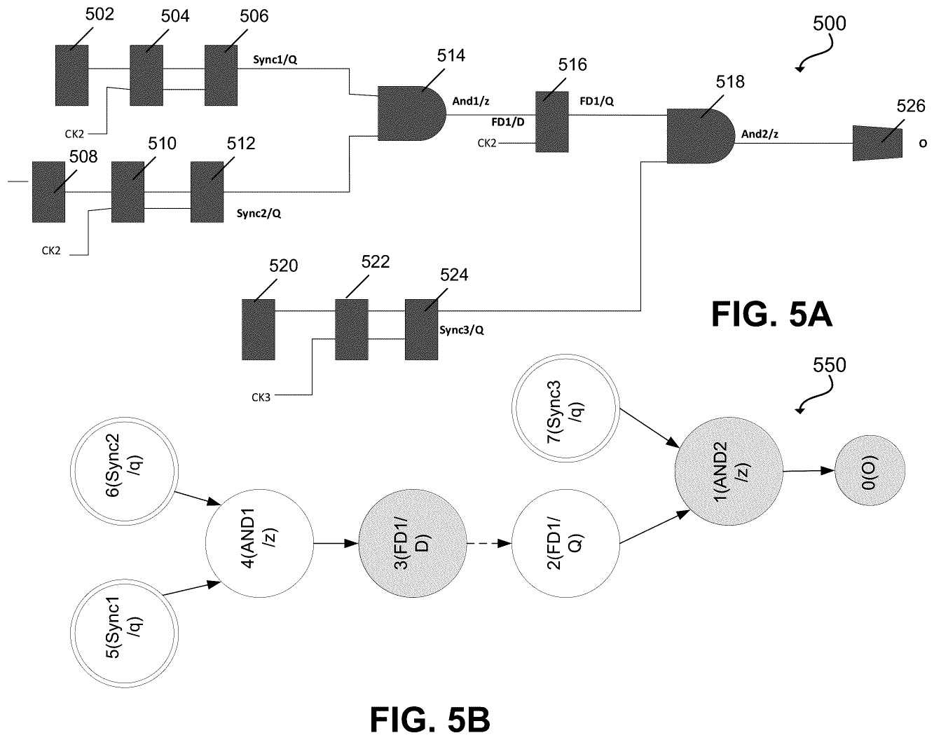

FIG. 5A illustrates a block diagram of an integrated circuit (IC) 500 for performing a clock relationship based re-convergence analysis, in accordance with an embodiment of the present disclosure. IC 500 includes flip-flops 502, 504, 506, driven by CK2, flip-flops 508, 510, 512, also driven by CK2, and an AND gate 514. The IC 500 further includes flip-flops 520, 522, 524 driven by CK3, and an AND gate 518 that combines the signal from flip-flop 516 and 524. The IC 500 further includes a port 526 with an output O.

FIG. 5B illustrates a levelized topological abstract graph (LTAG) 550 including a network of nodes 0-7, in accordance with an embodiment of the present disclosure. The topological sorted levelized abstract graph 550 is created in order to facilitate a very fast traversal (e.g., breadth-first search (BFS)) and data-propagation over the graph. This graph 550 is created in a linear order by traversing over the fan-out-cone circuit of the detected synchronizers. Levelization (e.g., traversal only on one level instead of a complete cone) is done by breaking the connectivity between the register outputs and inputs. The graph may be levelized in such a manner that each level may have a set of nodes which may not have value dependencies, and each node may include a CDC synchronizer or a circuit element. This facilitates in breaking any combinational loops in the design thus helping in true topological sorting of the graph. A pseudo connectivity (e.g., a logical or physical connection) is preserved for broken connectivity to facilitate data-propagation. For example, connectivity information may be preserved and used for analysis and to remove loops. This graph 550 is abstracted by compressing the connectivity of the circuit elements which are redundant for re-convergence analysis perspective. Topological sort property of this graph facilitates a liner order travel to propagate any information over the graph.

The next operation involves potential re-convergence analysis, which helps in identifying the potential re-convergence violations. At each node, which may include one or more CDC synchronizers or circuit elements, the data on all the input nodes is unionized and if the unionized data is such that none of the input-data matches with the output data then it is considered as a potential re-convergence violation. For example, if graph node G1 has fan-in graph node G2, G3, and G4 drivers, then unionizing in this case would mean union of data on fan-in graph nodes G2, G3, and G4. In the example shown in FIG. 5A, there would be two potential re-convergence violations: Sync1/Q and Sync2/Q->And1/z, and Sync1/Q, Sync2/Q and Sync3/Q->And2/z.

The next operation involves creating subsets. Based on the clock-relationship among the converging synchronizers subsets are created to split the potential re-convergence violations into actual re-convergence violations. In the example shown in FIG. 5A, for the two potential re-convergence violations, the subsets would be as following: At And1/z->“Sync1/Q, Sync2/Q” can be the only subset as both the synchronizers have a synchronous clock-relation, and at And2/z->“Sync1/Q, Sync2/Q” and “Sync3/Q” can be two subsets, Sync1/Q and Sync2/Q have synchronous clock-relation, whereas Sync3/Q have asynchronous relationship.

The next operation involves duplicate re-convergence suppressing. After creation of actual violations in the previous operation for each potential re-convergence violation, there is a possibility that duplication re-convergence violation may be created. These duplication violations must be suppressed to avoid noisy results. To suppress the duplication violations on each gate, subsets on the gates in immediate fan-in cone are compared subsets on the current gate and if the subset are matched, then the violation corresponding to matched subset on current gate is suppressed (marked as false). In the example shown in FIG. 5A, the violation of Sync1/Q, Sync2/Q at gate And2/z is suppressed by a same re-convergence violation at gate And1/z. Since Sync3/Q is a single synchronizer subset, it is marked invalid as it does not represent a re-convergence.

The next operation involves end point propagation. All the unsuppressed actual violations are then propagated over the topological graph to end-points (e.g., sequential register, black-boxes, primary ports). If the end-point has a synchronous clock-relationship with the synchronizers of the re-convergence violation, then such an end-point is considered valid for the re-convergence violation. If a re-convergence violation is not propagated to any valid end-point, then it is considered redundant and is marked as invalid/suppressed. All the unsuppressed re-convergence violations are then reported to user for analysis. In the example shown in FIG. 5A, for Sync1/Q, Sync2/Q re-convergence violation at And1/z, the FD1/d would be considered as a valid end-point and hence a violation would be reported.

Accordingly, one embodiment is a computer-implemented method for assisting verification of designs of electronic circuitry. The method may include a levelized topological circuit abstraction operation, a potential re-convergence analysis operation, a subset creation operation, a duplicate re-convergence suppressing operation, and an end point propagation operation. The levelized topological circuit abstraction operation includes creation of a topological sorted levelized abstract graph in order to facilitate a very fast traversal and data-propagation over the graph. This graph is created in a linear order by traversing over the fanout-cone circuit of the detected synchronizers. Levelization is done by breaking the connectivity between the register outputs and inputs. The graph may be levelized in such a manner that each level may have a set of nodes which may not have value dependencies, and each node may include a CDC synchronizer or a circuit element. This facilitates in breaking any combinational loops in the design thus helping in true topological sorting of the graph. A pseudo connectivity (e.g., a logical or physical connection) is preserved for broken connectivity to facilitate data-propagation. This graph is abstracted by compressing the connectivity of the circuit elements which are redundant for re-convergence analysis perspective. Topological sort property of this graph facilitates a linear order travel to propagate any information over the graph.

The potential re-convergence analysis operation includes in identifying the potential re-convergence violations. At each node, the data on all the input nodes is unionized and if the unionized data is such that none of the input-data matches with the output data then it is considered as a potential re-convergence violation. The subset creation operation includes creating subsets based on the clock-relationship among the converging synchronizers subsets are created to split the potential re-convergence violations into actual re-convergence violations. The duplicate re-convergence suppressing operation includes comparing subsets on the gates in immediate fan-in cone and subsets on the current gate and if the subset are matched, then the violation corresponding to matched subset on current gate is suppressed (marked false). This is performed to suppress the duplication violations on each gate. The end point propagation operation includes propagating all the unsuppressed actual violations over the topological graph to end-points (e.g., sequential register, black-boxes, and primary ports). If the end-point has a synchronous clock-relationship with the synchronizers of the re-convergence violation, then such an end-point is considered valid for the re-convergence violation. If a re-convergence violation is not propagated to any valid end-point, then it is considered redundant and is marked as invalid/suppressed. All the unsuppressed re-convergence violations are then reported to user for analysis.

Another embodiment is a non-transitory computer-readable storage medium storing executable computer program instructions for assisting hardware emulation, the instructions executable by a processor and causing the processor to perform a method comprising: a levelized topological circuit abstraction operation, a potential re-convergence analysis operation, a subset creation operation, a duplicate re-convergence suppressing operation, and an end point propagation operation, described above.

The methods and systems disclosed herein can be integrated into a simulation tool. Such a simulation tool may be able to identify potential chip killer issues at the RTL implementation stage. Additionally, end-point analysis provided in the disclosed systems and methods results in reduction of noisy violations thus reducing a bandwidth requirement from the user. The methods and systems disclosed are highly performance optimized for better turnaround time for solving a complex problem.

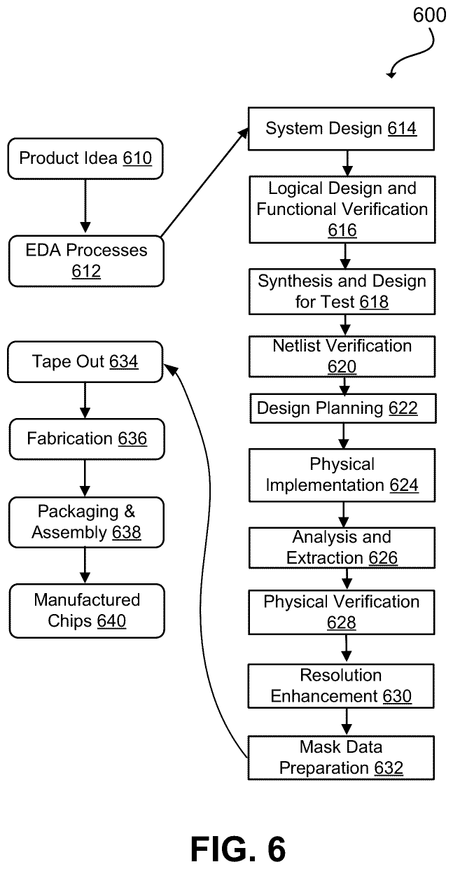

FIG. 6 illustrates an example set of processes 600 used during the design, verification, and fabrication of an article of manufacture such as an integrated circuit to transform and verify design data and instructions that represent the integrated circuit. Each of these processes can be structured and enabled as multiple modules or operations. The term ‘EDA’ signifies the term ‘Electronic Design Automation.’ These processes can start with the creation of a product idea 610 with information supplied by a designer, information which is transformed to create an article of manufacture that uses a set of EDA processes 612. When the design is finalized, the design is taped-out 634, which is when artwork (e.g., geometric patterns) for the integrated circuit is sent to a fabrication facility to manufacture the mask set, which is then used to manufacture the integrated circuit. After tape-out, a semiconductor die can be fabricated 636 and packaging and assembly processes 638 can be performed to produce the finished integrated circuit 640.

Specifications for a circuit or electronic structure may range from low-level transistor material layouts to high-level description languages. A high-level of abstraction may be used to design circuits and systems, using a hardware description language (‘HDL’) such as VHDL, Verilog, SystemVerilog, SystemC, MyHDL or OpenVera. The HDL description can be transformed to a logic-level register transfer level (‘RTL’) description, a gate-level description, a layout-level description, or a mask-level description. Each lower abstraction level that is a less abstract description adds more useful detail into the design description, for example, more details for the modules that include the description. The lower levels of abstraction that are less abstract descriptions can be generated by a computer, derived from a design library, or created by another design automation process. An example of a specification language at a lower level of abstraction language for specifying more detailed descriptions is SPICE, which can be used for detailed descriptions of circuits with many analog components. Descriptions at each level of abstraction are enabled for use by the corresponding tools of that layer (e.g., a formal verification tool). A design process may use a sequence depicted in FIG. 6. The processes described herein can be enabled by EDA products (or tools).

During system design 614, functionality of an integrated circuit to be manufactured is specified. The design may be optimized for desired characteristics such as power consumption, performance, area (physical and/or lines of code), and reduction of costs, etc. Partitioning of the design into different types of modules or components can occur at this stage.

During logic design and functional verification 616, modules or components in the circuit can be specified in one or more description languages and the specification can be checked for functional accuracy. For example, the components of the circuit may be verified to generate outputs that match the requirements of the specification of the circuit or system being designed. Functional verification may use simulators and other programs such as testbench generators, static HDL checkers, and formal verifiers. In some embodiments, special systems of components referred to as ‘emulators’ or ‘prototyping systems’ can be used to speed up the functional verification.

During synthesis and design for test 618, HDL code can be transformed to a netlist. In some embodiments, a netlist may be a graph structure where edges of the graph structure represent components of a circuit and where the nodes of the graph structure represent how the components are interconnected. Both the HDL code and the netlist are hierarchical articles of manufacture that can be used by an EDA product to verify that the integrated circuit, when manufactured, performs according to the specified design. The netlist can be optimized for a target semiconductor manufacturing technology. Additionally, the finished integrated circuit may be tested to verify that the integrated circuit satisfies the requirements of the specification.

During netlist verification 620, the netlist can be checked for compliance with timing constraints and for correspondence with the HDL code. During design planning 622, an overall floor plan for the integrated circuit can be constructed and analyzed for timing and top-level routing.

During layout or physical implementation 624, physical placement (positioning of circuit components such as transistors or capacitors) and routing (connection of the circuit components by multiple conductors) can occur, and the selection of cells from a library to enable specific logic functions can be performed. As used herein, the term ‘cell’ may specify a set of transistors, other components, and interconnections that provides a Boolean logic function (e.g., AND, OR, NOT, XOR) or a storage function (such as a flip-flop or latch). As used herein, a circuit ‘block’ may refer to two or more cells. Both a cell and a circuit block can be referred to as a module or component and can be enabled as both physical structures and in simulations. Parameters can be specified for selected cells (based on ‘standard cells’) such as size and made accessible in a database for use by EDA products.

During analysis and extraction 626, the circuit function can be verified at the layout level, which permits refinement of the layout design. During physical verification 628, the layout design can be checked to ensure that manufacturing constraints are correct, such as DRC constraints, electrical constraints, lithographic constraints, and that circuitry function matches the HDL design specification. During resolution enhancement 630, the geometry of the layout can be transformed to improve how the circuit design is manufactured.

During tape-out, data can be created to be used (after lithographic enhancements are applied if appropriate) for production of lithography masks. During mask data preparation 632, the ‘tape-out’ data is used to produce lithography masks that are used to produce finished integrated circuits.

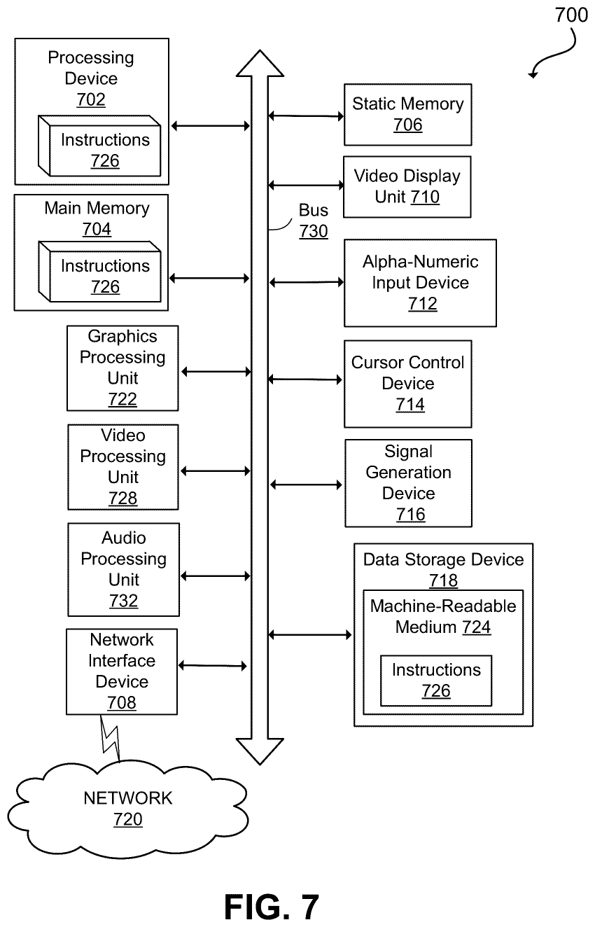

A storage subsystem of a computer system (such as computer system 700 of FIG. 7) may be used to store the programs and data structures that are used by some or all of the EDA products described herein, and products used for development of cells for the library and for physical and logical design that use the library.

FIG. 7 illustrates an example machine of a computer system 700 within which a set of instructions, for causing the machine to perform any one or more of the methodologies discussed herein, may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 700 includes a processing device 702, a main memory 704 (e.g., read-only memory (ROM), flash memory, dynamic random access memory (DRAM) such as synchronous DRAM (SDRAM), a static memory 706 (e.g., flash memory, static random access memory (SRAM), etc.), and a data storage device 718, which communicate with each other via a bus 730.

Processing device 702 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 702 may also be one or more special-purpose processing devices such as an application specific integrated circuit (ASIC), a field programmable gate array (FPGA), a digital signal processor (DSP), network processor, or the like. The processing device 702 may be configured to execute instructions 726 for performing the operations and steps described herein.

The computer system 700 may further include a network interface device 708 to communicate over the network 720. The computer system 700 also may include a video display unit 710 (e.g., a liquid crystal display (LCD) or a cathode ray tube (CRT)), an alphanumeric input device 712 (e.g., a keyboard), a cursor control device 714 (e.g., a mouse), a graphics processing unit 722, a signal generation device 716 (e.g., a speaker), graphics processing unit 722, video processing unit 728, and audio processing unit 732.

The data storage device 718 may include a machine-readable storage medium 724 (also known as a non-transitory computer readable medium) on which is stored one or more sets of instructions 726 or software embodying any one or more of the methodologies or functions described herein. The instructions 726 may also reside, completely or at least partially, within the main memory 704 and/or within the processing device 702 during execution thereof by the computer system 700, the main memory 704 and the processing device 702 also constituting machine-readable storage media.

In one embodiment, the non-transitory computer readable medium may include instructions 726 which when executed by a processing device (e.g., processing device 702), cause the processing device to generate a digital representation of a level-shifting circuit. The level-shifting circuit may include a level shifter configured to receive a first clock signal associated with a first power level (VDDP) and generate a second clock signal associated with a second power level (VDDA). The second power level may be greater than the first power level. The level-shifting circuit may further include an input clock buffer including a first input including the second clock signal from the level shifter, and a second input coupled in parallel to the first input; the second input including the first clock signal. In one embodiment, the first power level includes a peripheral voltage and the second power level includes a bitcell array voltage. The input clock buffer may be configured to generate an output clock signal when a difference between the second power level and the first power level is above a determined threshold voltage, and generate the output clock signal when the difference between the second power level and the first power level is below the determined threshold voltage. The output clock signal may be provided as inputs to a memory periphery and a memory timer, and the memory periphery and memory timer may be coupled in parallel to the input clock buffer.

In some implementations, the instructions 726 include instructions to implement functionality corresponding to the present disclosure. While the machine-readable storage medium 724 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 702 to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

What is claimed is:

1. A method comprising:
receiving, by a processing device, a register-transfer level (RTL) description of a design relating to an integrated circuit (IC);
identifying one or more clock domain crossing (CDC) synchronizers in the RTL description of the design;
generating a graph comprising a network of nodes, wherein each node comprises a CDC synchronizer;
traversing the graph starting from a first output of the one or more CDC synchronizers; and
responsive to determining that a first CDC synchronizer of the one or more CDC synchronizers is converging with a second CDC synchronizer, identifying a first potential convergence violation associated with the first CDC synchronizer and the second CDC synchronizer.

2. The method of claim 1, further comprising:
identifying a plurality of converging CDC synchronizers;
creating one or more subsets comprising one or more of the plurality of converging CDC synchronizers based on a clock-relationship between the plurality of converging CDC synchronizers;
traversing the graph starting from a second output of the one or more CDC synchronizers;
comparing a first subset at a gate in the IC to a second subset on a fan-in node in the network of nodes; and
responsive to determining that the first subset matches with the second subset, identifying the first subset as suppressed.

3. The method of claim 2, further comprising:
propagating each unsuppressed convergence over the graph to one or more end points, wherein the one or more end points is selected from a group consisting of sequential registers, clocks, black-boxes, and primary ports; and
responsive to determining that a first end point has a synchronous clock relationship with the first CDC synchronizer, identifying the first end point as a second potential convergence violation.

4. The method of claim 3, further comprising:
suppressing one or more converging CDC synchronizers with no end points; and
generating a report comprising one or more unsuppressed converging CDC synchronizers.

5. The method of claim 1, wherein generating the graph further comprises:
traversing, in a linear order, over a fan-out cone circuit of the one or more CDC synchronizers identified; and
breaking connectivity between an input and output of a register of the one or more CDC synchronizers, while preserving a pseudo-connectivity to facilitate data propagation.

6. The method of claim 1, wherein identifying the first potential convergence violation further comprises:
unionizing, at each node of the network of nodes, data on a plurality of input nodes to generate unionized data; and
determining that input data does not match with output data of the unionized data.

7. The method of claim 3, wherein the first and second potential convergence violations comprise at least one of a combinational convergence or a sequential convergence.

8. A non-transitory computer readable medium comprising stored instructions, which when executed by a processor, cause the processor to:
receive a register-transfer level (RTL) description of a design relating to an integrated circuit (IC);
identify one or more clock domain crossing (CDC) synchronizers in the RTL description of the design;
generate a graph comprising a network of nodes, each node comprising a CDC synchronizer;
traverse the graph starting from a first output of the one or more CDC synchronizers; and
responsive to determining that a first CDC synchronizer of the one or more CDC synchronizers is converging with a second CDC synchronizer, identify a first potential convergence violation associated with the first CDC synchronizer and the second CDC synchronizer.

9. The non-transitory computer readable medium of claim 8, comprising further instructions to cause the processor to:
identify a plurality of converging CDC synchronizers;
create one or more subsets comprising one or more of the plurality of converging CDC synchronizers based on a clock-relationship between the plurality of converging CDC synchronizers;
traverse the graph starting from a second output of the one or more CDC synchronizers;
compare a first subset at a gate in the IC to a second subset on a fan-in node in the network of nodes; and
responsive to determining that the first subset matches with the second subset, identify the first subset as suppressed.

10. The non-transitory computer readable medium of claim 9, comprising further instructions to cause the processor to:
propagate each unsuppressed convergence over the graph to one or more end points, wherein the one or more end points is selected from a group consisting of sequential registers, clocks, black-boxes, and primary ports; and
responsive to determining that a first end point has a synchronous clock relationship with the first CDC synchronizer, identify the first end point as a second potential convergence violation.

11. The non-transitory computer readable medium of claim 10, comprising further instructions to cause the processor to:
suppress one or more converging CDC synchronizers with no end points; and
generate a report comprising one or more unsuppressed converging CDC synchronizers.

12. The non-transitory computer readable medium of claim 8, wherein generating the graph further comprises:
traverse, in a linear order, over a fan-out cone circuit of the one or more CDC synchronizers identified; and
break connectivity between an input and output of a register of the one or more CDC synchronizers, while preserving a pseudo-connectivity to facilitate data propagation.

13. The non-transitory computer readable medium of claim 8, wherein identifying the first potential convergence violation further comprises:
unionize, at each node of the network of nodes, data on a plurality of input nodes to generate unionized data; and
determine that input data does not match with output data of the unionized data.

14. The non-transitory computer readable medium of claim 10, wherein the first and second potential convergence violations comprise at least one of a combinational convergence or a sequential convergence.

15. A system comprising:
a processor; and
a memory storing instructions, which when executed by the processor, cause the processor to perform operations comprising:
receiving a register-transfer level (RTL) description of a design relating to an integrated circuit (IC);
identifying one or more clock domain crossing (CDC) synchronizers in the RTL description of the design;
generating a graph comprising a network of nodes, wherein each node comprises a CDC synchronizer;
traversing the graph starting from a first output of the one or more CDC synchronizers; and
responsive to determining that a first CDC synchronizer of the one or more CDC synchronizers is converging with a second synchronizer, identifying a first potential convergence violation associated with the first CDC synchronizer and the second CDC synchronizer.

16. The system of claim 15, wherein the operations further comprise:
identifying a plurality of converging CDC synchronizers;
creating one or more subsets comprising one or more of the plurality of converging CDC synchronizers based on a clock-relationship between the plurality of converging CDC synchronizers;
traversing the graph starting from a second output of the one or more CDC synchronizers;
comparing a first subset at a gate in the IC to a second subset on a fan-in node in the network of nodes; and
responsive to determining that the first subset matches with the second subset, identifying the first subset as suppressed.

17. The system of claim 16, wherein the operations further comprise:
propagating each unsuppressed convergence over the graph to one or more end points, wherein the one or more end points is selected from a group consisting of sequential registers, clocks, black-boxes, and primary ports; and
responsive to determining that a first end point has a synchronous clock relationship with the first CDC synchronizer, identifying the first end point as a second potential convergence violation.

18. The system of claim 17, wherein the operations further comprise:
suppressing one or more converging CDC synchronizers with no end points; and
generating a report comprising one or more unsuppressed converging CDC synchronizers.

19. The system of claim 15, wherein generating the graph further comprises:
traversing, in a linear order, over a fan-out cone circuit of the one or more CDC synchronizers identified; and
breaking connectivity between an input and output of a register of the one or more CDC synchronizers, while preserving a pseudo-connectivity to facilitate data propagation.

20. The system of claim 15, wherein identifying the first potential convergence violation further comprises:
unionizing, at each node of the network of nodes, data on a plurality of input nodes to generate unionized data; and
determining that input data does not match with output data of the unionized data.
